(19) United States
(12) Patent Application Publication
(10) Pub. No.: US 2025/0100020 A1
(43) Pub. Date: Mar. 27, 2025

(54) NOZZLE POSITION ADJUSTING DEVICE, NOZZLE POSITION ADJUSTING METHOD, AND NOZZLE POSITION ADJUSTING HOLDER

(71) Applicant: EBARA CORPORATION, Tokyo (JP)

(72) Inventors: Junya IKEGAMI, Tokyo (JP); Shuichi SUEMASA, Tokyo (JP)

(21) Appl. No.: 18/889,575

(22) Filed: Sep. 19, 2024

(30) Foreign Application Priority Data
Sep. 22, 2023 (JP) 2023-156625

(51) Int. Cl. B08B 3/02; H01L 21/67

(52) U.S. Cl. CPC B08B 3/02; B08B 2203/02; H01L 21/67051

(57) ABSTRACT

A nozzle position adjusting device is used for a substrate cleaning device including a substrate support portion that supports a substrate and a nozzle that jets a cleaning liquid toward the substrate. The nozzle position adjusting device includes a position confirmation plate in which a position display is formed and which is installed in the substrate support portion, and a positioning mechanism configured to extend from the nozzle toward the position confirmation plate. The positioning mechanism determines the position of the nozzle with respect to the position confirmation plate by using the position display.

### BACKGROUND OF THE INVENTION

### Field of the Invention

Priority is claimed on Japanese Patent Application No. 2023-156625, filed Sep. 22, 2023, the content of which is incorporated herein by reference.

The present invention relates to a nozzle position adjusting device, a nozzle position adjusting method, and a nozzle position adjusting holder.

### Description of Related Art

In a substrate cleaning device including a nozzle that jets a cleaning liquid to a substrate such as a semiconductor wafer, a device that adjusts the position of the nozzle is used (for example, refer to Japanese Unexamined Patent Application, First Publication No. 2017-183595).

### SUMMARY OF THE INVENTION

However, in the device, it is not easy to accurately adjust the position of the nozzle. Therefore, in some cases, the liquid cannot be jetted to an accurate position with respect to the substrate.

An aspect of the present invention aims to provide a nozzle position adjusting device, a nozzle position adjusting method, and a nozzle position adjusting holder which can accurately adjust the position of a nozzle.

According to an aspect 1 of the present invention, there is provided a nozzle position adjusting device used for a substrate cleaning device including a substrate support portion that supports a substrate and a nozzle that jets a cleaning liquid toward the substrate. The nozzle position adjusting device includes a position confirmation plate in which a position display is formed and which is installed in the substrate support portion, and a positioning mechanism configured to extend from the nozzle toward the position confirmation plate. The positioning mechanism determines the position of the nozzle with respect to the position confirmation plate by using the position display.

As the nozzle position adjusting device according to an aspect 2 of the present invention, in the nozzle position adjusting device according to the aspect 1, the positioning mechanism may include a holder and a rod held by the holder to be expandable and contractible in a direction closer to and away from the position confirmation plate. The position of the nozzle may be determined, based on the position of a tip of the rod with respect to the position display.

As the nozzle position adjusting device according to an aspect 3 of the present invention, in the nozzle position adjusting device according to the aspect 2, one or a plurality of engagement recesses may be formed in the position confirmation plate. The tip of the rod may be engageable with the engagement recess. The positioning mechanism may determine the position of the rod by the tip being engaged with the engagement recess.

As the nozzle position adjusting device according to an aspect 4 of the present invention, in the nozzle position adjusting device according to the aspect 3, the position display may have a lattice-shaped reference line. The engagement recess may be formed at an intersection of the reference line.

According to an aspect 5 of the present invention, there is provided a nozzle position adjusting method including installing a position confirmation plate having a position display in a substrate support portion, before cleaning a substrate with a substrate cleaning device including the substrate support portion that supports the substrate and a nozzle that jets a cleaning liquid toward the substrate, and causing a positioning mechanism configured to extend from the nozzle toward the position confirmation plate to determine the position of the nozzle with respect to the position confirmation plate by using the position display.

According to an aspect 6 of the present invention, there is provided a nozzle position adjusting holder used for a substrate cleaning device including a substrate support portion that supports a substrate and a nozzle that jets a cleaning liquid toward the substrate. The nozzle position adjusting holder is used for a nozzle position adjusting device including a position confirmation plate having a position display and installed in the substrate support portion, and a positioning mechanism having a rod and extending from the nozzle toward the position confirmation plate. The nozzle position adjusting holder holds the rod to be expandable and contractible in a direction closer to and away from the position confirmation plate.

According to an aspect of the present invention, it is possible to provide a nozzle position adjusting device, a nozzle position adjusting method, and a nozzle position adjusting holder which can accurately adjust the position of a nozzle.

### BRIEF DESCRIPTION OF THE DRAWINGS

FIG. 1 is a perspective view of a substrate cleaning device.

FIG. 2 is a plan view of the substrate cleaning device.

FIG. 3 is a front view of the substrate cleaning device.

FIG. 4 is a perspective view of a nozzle of the substrate cleaning device.

FIG. 5 is a cross-sectional view of a base body of the nozzle of the substrate cleaning device.

FIG. 6 is a front view of a nozzle position adjusting device according to a first embodiment.

FIG. 7 is a front view showing an enlarged part of the nozzle position adjusting device according to the first embodiment.

FIG. 8 is a front view showing an enlarged part of the nozzle position adjusting device according to the first embodiment.

FIG. 9 is a plan view of a position confirmation plate.

FIG. 10 is a plan view showing an enlarged part of the position confirmation plate.

FIG. 11 is a front view of a nozzle position adjusting device according to a second embodiment.

### DETAILED DESCRIPTION OF THE INVENTION

Hereinafter, embodiments of a nozzle position adjusting device, a nozzle position adjusting method, and a nozzle position adjusting holder according to the present invention will be described with reference to the drawings.

### Substrate Cleaning Device

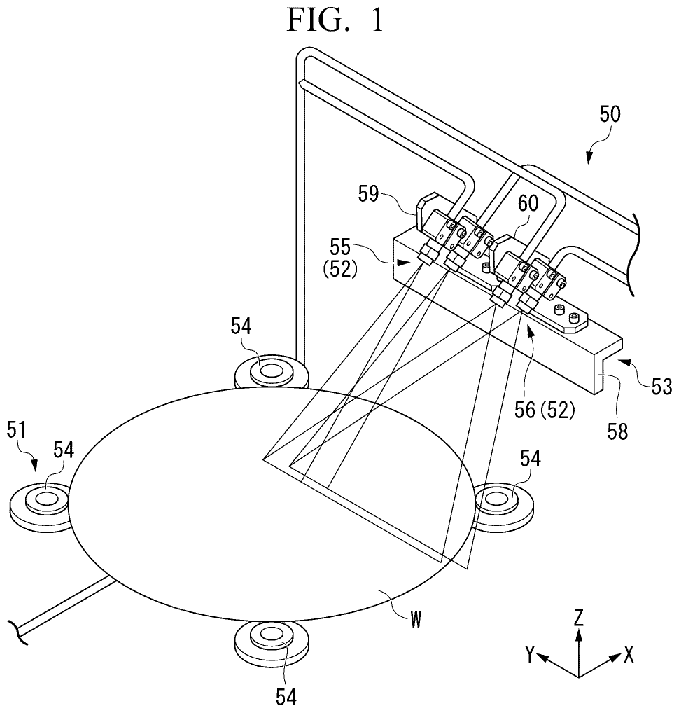

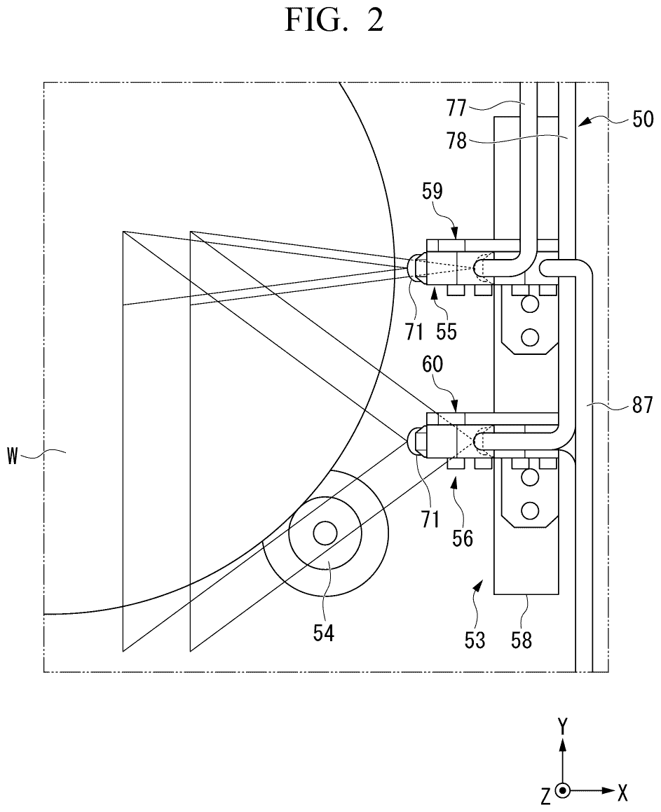

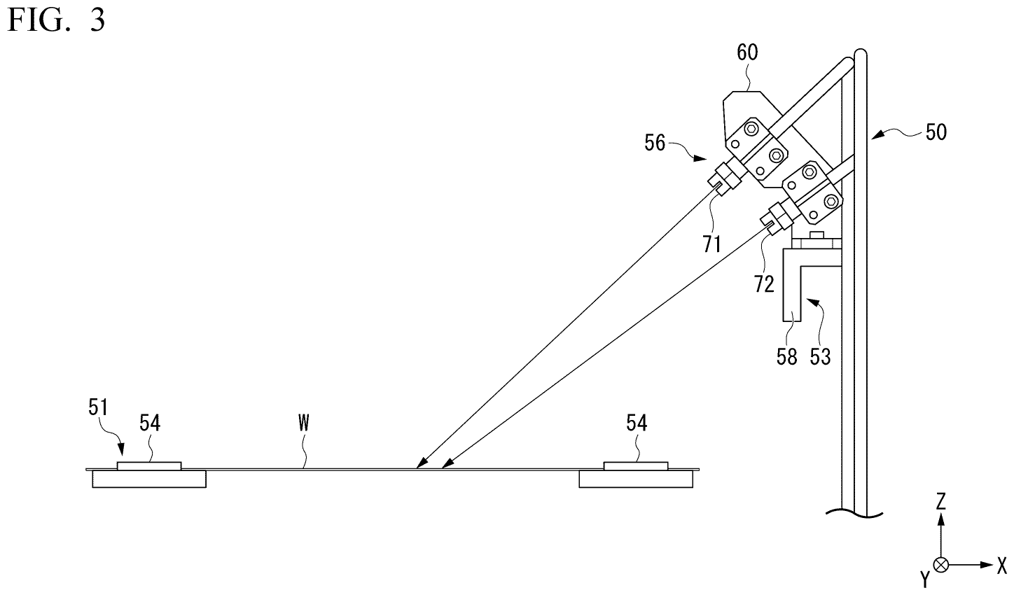

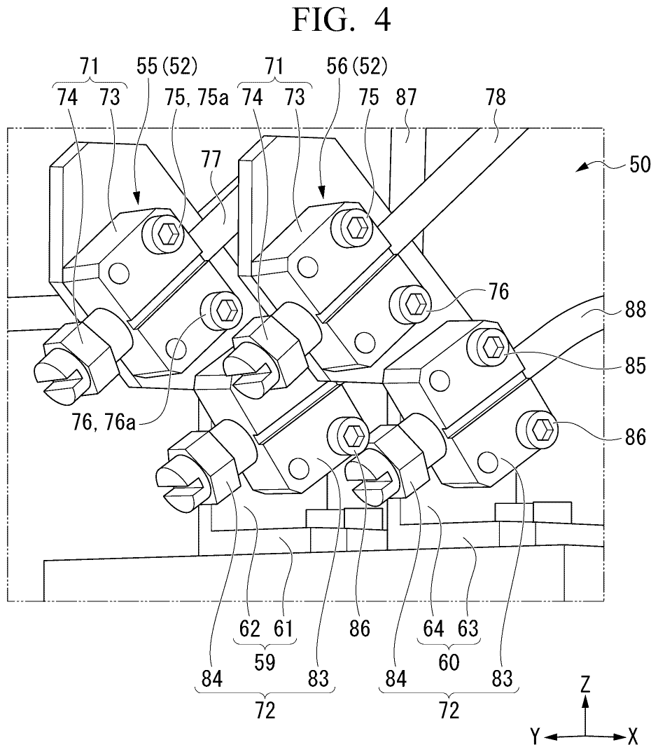

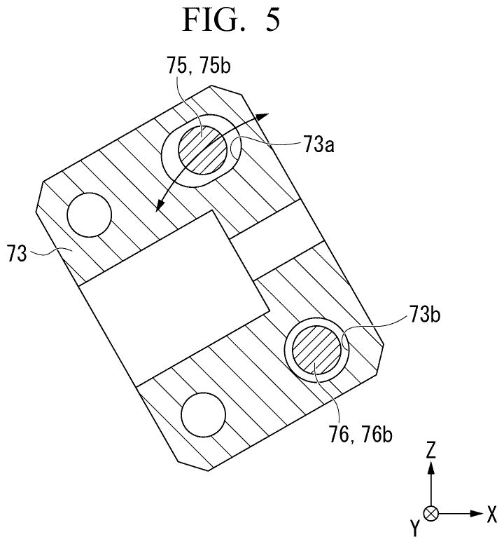

FIG. 1 is a perspective view of a substrate cleaning device. FIG. 2 is a plan view of the substrate cleaning device. FIG. 3 is a front view of the substrate cleaning device. FIG. 4 is a perspective view of a nozzle of the substrate cleaning device. FIG. 5 is a cross-sectional view of a base body of the nozzle of the substrate cleaning device.

As shown in FIGS. 1 to 3, a substrate cleaning device 50 (substrate treatment device) cleans a surface of a substrate W while rotating the substrate W around a center axis of the substrate W under a presence of a cleaning liquid. For example, as the substrate W, a semiconductor wafer can be used.

The substrate cleaning device 50 includes a substrate support portion 51, a plurality of liquid supply portions 52, a support portion 53, and a cleaning member (not shown).

The substrate support portion 51 includes a plurality of spindles 54 (holding portions) that hold a peripheral edge portion of the substrate W. The spindle 54 supports the substrate W to be rotatable in a circumferential direction. For example, the substrate support portion 51 can support the substrate W in a horizontal posture. For example, the number of the spindles 54 is four.

In the following description, an XYZ rectangular coordinate system may be used in some cases. An X-direction and a Y-direction are directions along a plane defined by the plurality of spindles 54. The X-direction and the Y-direction are orthogonal to each other. AZ-direction is orthogonal to the X-direction and the Y-direction. A plan view means a view in the Z-direction. A plane along the X-direction and the Y-direction will be referred to as an “XY-plane”. For example, the XY-plane is a horizontal plane. A plane along the X-direction and the Z-direction will be referred to as an “XZ-plane”.

The support portion 53 includes a support frame 58 and support bodies 59 and 60. For example, the support frame 58 has an L-shape in a cross section, and extends in the Y-direction. For example, an upper surface of the support frame 58 is parallel to the XY-plane. The support bodies 59 and 60 are a first support body 59 and a second support body 60. The support bodies 59 and 60 are provided on the upper surface of the support frame 58. The first support body 59 and the second support body 60 are provided at different positions in a longitudinal direction (Y-direction) of the support frame 58.

As shown in FIG. 4, the first support body 59 supports a first liquid supply portion 55. The first support body 59 includes a first base portion 61 and a first attachment portion 62. The first base portion 61 has a plate shape. The first base portion 61 is attached to the upper surface of the support frame 58. For example, the first base portion 61 is parallel to the XY-plane.

The first attachment portion 62 has a plate shape. The first attachment portion 62 is erected with respect to the first base portion 61. For example, the first attachment portion 62 is perpendicular to the first base portion 61. For example, the first attachment portion 62 is parallel to the XZ-plane.

The second support body 60 supports a second liquid supply portion 56. The second support body 60 includes a second base portion 63 and a second attachment portion 64. The second base portion 63 has a plate shape. The second base portion 63 is attached to the upper surface of the support frame 58. For example, the second base portion 63 is parallel to the XY-plane.

The second attachment portion 64 has a plate shape. The second attachment portion 64 is erected with respect to the second base portion 63. For example, the second attachment portion 64 is perpendicular to the second base portion 63. For example, the second attachment portion 64 is parallel to the XZ-plane.

For example, the cleaning member is a roll cleaning member, a pencil cleaning member, or the like.

The plurality of liquid supply portions 52 include a first liquid supply portion 55 and a second liquid supply portion 56.

The first liquid supply portion 55 supplies a cleaning liquid to a central portion of the substrate W (refer to FIG. 1). The second liquid supply portion 56 supplies a cleaning liquid to a wide region from the central portion to a peripheral edge portion of the substrate W. The “cleaning liquid” may be a chemical liquid, or may be a rinsing liquid. Examples of the chemical liquid include ammonia hydrogen peroxide (SC1), hydrochloric acid hydrogen peroxide (SC2), sulfuric acid hydrogen peroxide (SPM), sulfuric acid water, and fluorine acid. Examples of the rinsing liquid include ultrapure water and pure water (DIW).

The first liquid supply portion 55 includes nozzles 71 and 72. The nozzles 71 and 72 are a first nozzle 71 and a second nozzle 72.

The first nozzle 71 includes a first base body 73 (base body) and a first tip portion 74 (tip portion). The first base body 73 has a rectangular shape. Two insertion holes 73a and 73b that penetrate in a thickness direction are formed in the first base body 73 (refer to FIG. 5). The two insertion holes 73a and 73b are formed at different positions in the longitudinal direction of the first base body 73.

The first base body 73 is fixed to one surface of the first attachment portion 62 by two fixing tools 75 and 76. For example, the fixing tools 75 and 76 have head portions 75a and 76a and shaft portions 75b and 76b (for example, screw shafts) that extend from the head portions 75a and 76a. The shaft portions 75b and 76b are each inserted into the insertion holes 73a and 73b of the first base body 73 (refer to FIG. 5). The shaft portions 75b and 76b extend in the Y-direction. The tip portions of the shaft portions 75b and 76b are fixed to the first attachment portion 62. Outer diameters of the shaft portions 75b and 76b are smaller than outer diameters of the head portions 75a and 76a. The first base body 73 is pressed by the head portions 75a and 76a of the fixing tools 75 and 76 to be fixed to the first attachment portion 62.

An inner diameter of the insertion hole 73a into which the fixing tool 75 is inserted is larger than the outer diameter of the shaft portion 75b of the fixing tool 75. Therefore, an orientation of the first nozzle 71 can be adjusted by causing the first nozzle 71 to pivot around the fixing tool 76 (refer to an arrow shown in FIG. 5).

The first tip portion 74 protrudes from the first base body 73. The first tip portion 74 jets the chemical liquid supplied from a first supply pipe 77 toward the substrate W. A jetting direction of the chemical liquid is determined by the orientation of the first nozzle 71.

The second nozzle 72 includes a second base body 83 (base body) and a second tip portion 84 (tip portion). The second base body 83 has a rectangular shape. Two insertion holes are formed in the second base body 83. The two insertion holes are formed at different positions in the longitudinal direction of the second base body 83.

The second base body 83 is fixed to one surface of the first attachment portion 62 by two fixing tools 85 and 86. For example, the fixing tools 85 and 86 have a head portion and a shaft portion (for example, a screw shaft) that extends from the head portion. The shaft portion is inserted into the insertion hole of the second base body 83. The tip portion of the shaft portion is fixed to the first attachment portion 62. The second base body 83 is pressed by the head portions of the fixing tools 85 and 86 to be fixed to the first attachment portion 62.

The inner diameter of the insertion hole into which the fixing tool 85 is inserted is larger than the outer diameter of the shaft portion of the fixing tool 85. Therefore, the orientation of the second nozzle 72 can be adjusted by causing the second nozzle 72 to pivot around the fixing tool 86.

The second tip portion 84 protrudes from the second base body 83. The second tip portion 84 jets the rinsing liquid supplied from a second supply pipe 87 toward the substrate W. The jetting direction of the rinsing liquid is determined by the orientation of the second nozzle 72.

The second liquid supply portion 56 includes the nozzles 71 and 72.

The first base body 73 of the first nozzle 71 is fixed to one surface of the second attachment portion 64 by the two fixing tools 75 and 76. The orientation of the first nozzle 71 can be adjusted by causing the first nozzle 71 to pivot around the fixing tool 76.

The first tip portion 74 jets the chemical liquid supplied from the first supply pipe 78 toward the substrate W.

The second base body 83 of the second nozzle 72 is fixed to one surface of the second attachment portion 64 by the two fixing tools 85 and 86. The orientation of the second nozzle 72 can be adjusted by causing the second nozzle 72 to pivot around the fixing tool 86.

The second tip portion 84 jets the rinsing liquid supplied from a second supply pipe 88 toward the substrate W.

### Nozzle Position Adjusting Device

### First Embodiment

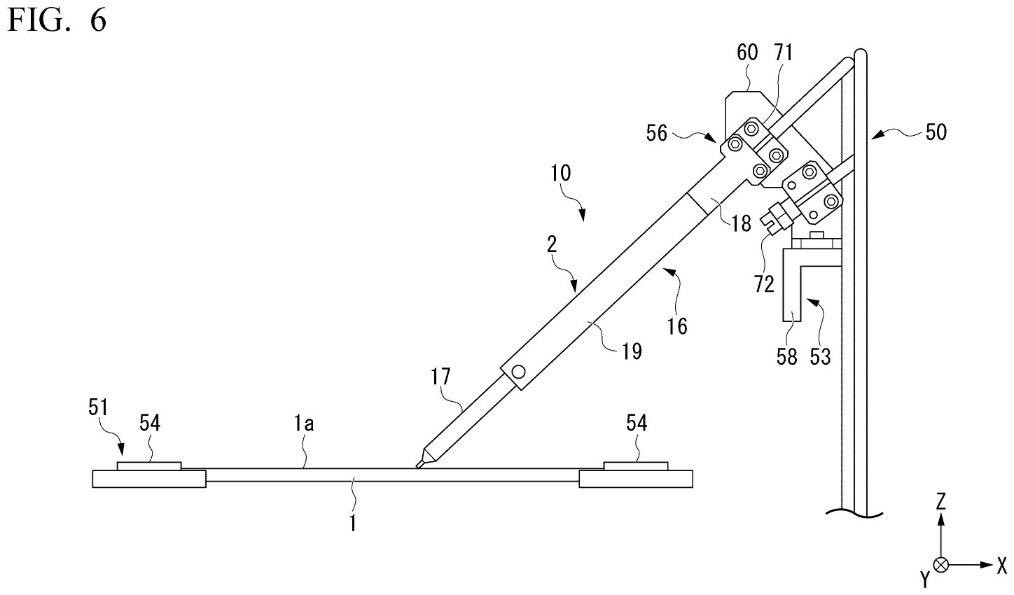

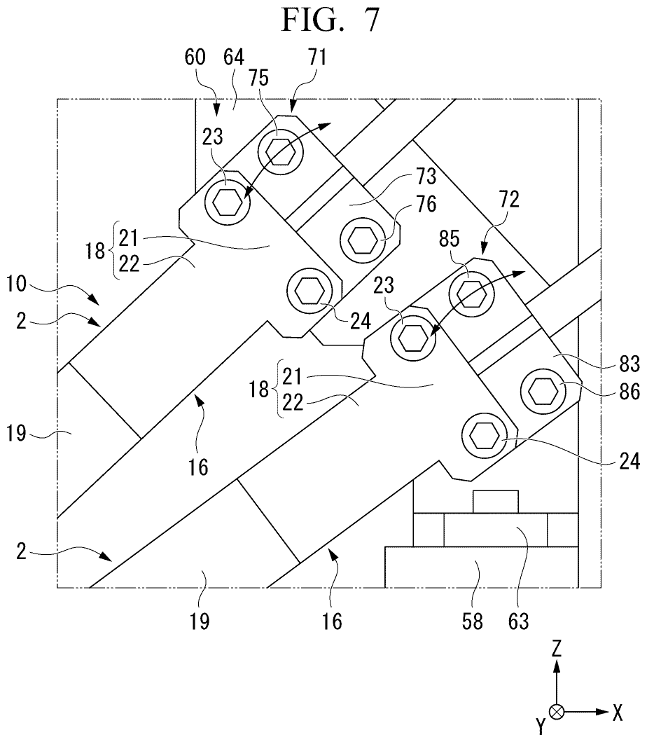

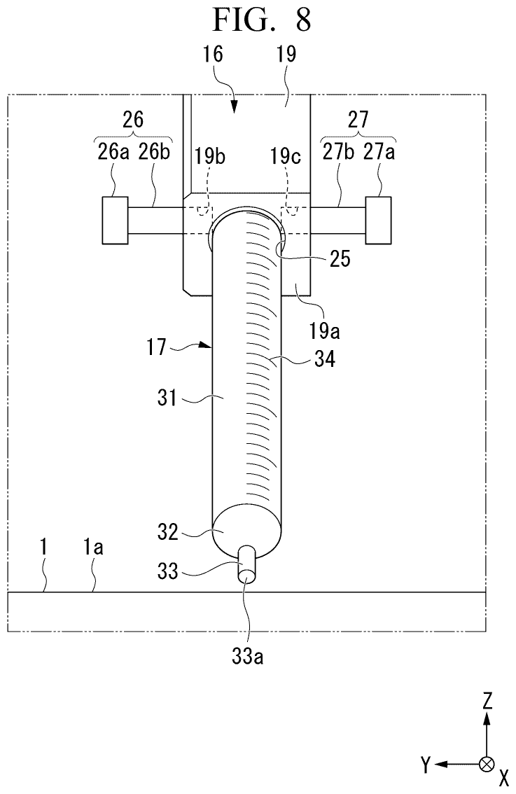

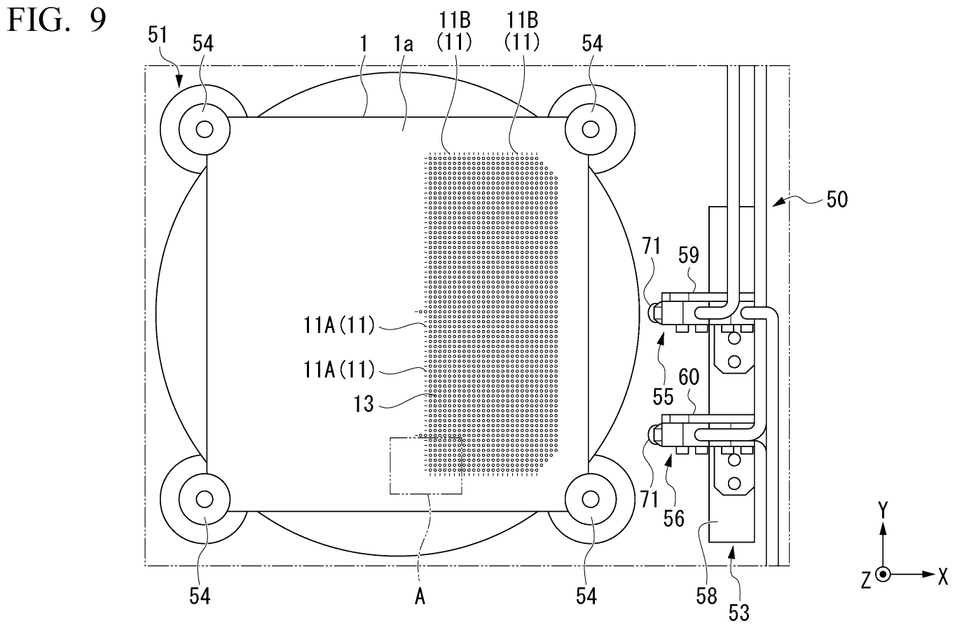

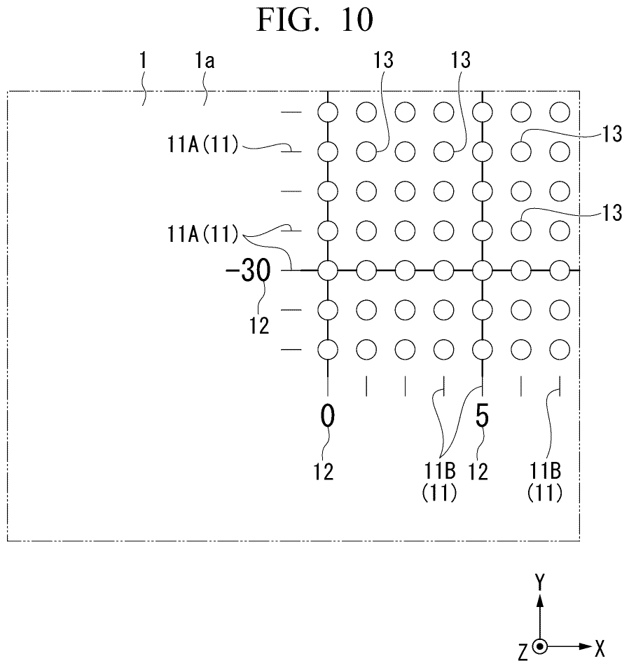

FIG. 6 is a front view of a nozzle position adjusting device 10 according to a first embodiment. FIG. 7 is a front view showing an enlarged part of the nozzle position adjusting device 10. FIG. 8 is a front view showing an enlarged part of the nozzle position adjusting device 10. FIG. 9 is a plan view of a position confirmation plate 1. FIG. 10 is a plan view showing an enlarged part of the position confirmation plate 1. FIG. 10 is an enlarged view of a region A shown in FIG. 9.

As shown in FIG. 6, the nozzle position adjusting device 10 includes the position confirmation plate 1 and one or a plurality of positioning mechanisms 2.

As shown in FIG. 9, for example, the position confirmation plate 1 is formed in a rectangular shape. For example, the thickness of the position confirmation plate 1 is the same as a thickness of the substrate W. The position confirmation plate 1 can be installed in the substrate support portion 51 instead of the substrate W (refer to FIG. 1). In the position confirmation plate 1, for example, four corner portions are each held by the spindles 54.

As shown in FIGS. 9 and 10, a position display 11 formed in a lattice shape and a scale 12 (refer to FIG. 10) are formed on a first main surface 1a (one surface) of the position confirmation plate 1. The position display 11 has a plurality of first reference lines 11A (reference lines) along the X-direction and a plurality of second reference lines 11B (reference lines) along the Y-direction. The plurality of first reference lines 11A are formed to be aligned at an interval in the Y-direction. The plurality of second reference lines 11B are formed to be aligned at an interval in the X-direction.

For example, the plurality of first reference lines 11A are formed at an equal interval. For example, the plurality of first reference lines 11A are formed at an equal interval. An interval between the adjacent first reference lines 11A and an interval between the adjacent second reference lines 11B are equal to each other. For example, the first reference line 11A and the second reference line 11B are formed in a grid shape. For example, the position display 11 indicates coordinates on the first main surface 1a. For example, the scale 12 indicates the position in the coordinates.

A plurality of engagement recesses 13 are formed on the first main surface 1a. It is desirable that the engagement recess 13 is formed to be associated with the position display 11. For example, the engagement recess 13 is formed at an intersection between the first reference line 11A and the second reference line 11B. For example, the engagement recess 13 has a circular shape in a plan view. For example, the engagement recess 13 is a hemispherical recess. The engagement recess 13 also functions as the position display.

As shown in FIG. 6, the positioning mechanism 2 can be attached to the nozzles 71 and 72. The positioning mechanism 2 extends from the attached nozzle toward the position confirmation plate 1. The positioning mechanism 2 is inclined to descend toward the tip.

The positioning mechanism 2 includes a holder 16 and a rod 17. The holder 16 includes an attachment portion 18 and a rod holding portion 19. The holder 16 is an example of a “nozzle position adjusting holder”.

As shown in FIG. 7, the attachment portion 18 includes a base portion 21 and an extending portion 22 that extends from the base portion 21. For example, the attachment portion 18 is formed in a plate shape parallel to the XY-plane.

The base portion 21 is formed in a rectangular shape. Two insertion holes are formed to penetrate the base portion 21. In the positioning mechanism 2 attached to the first nozzle 71, the base portion 21 is fixed to an outer surface of the first base body 73 by fixing tools 23 and 24. For example, the fixing tools 23 and 24 have a head portion and a shaft portion (for example, a screw shaft) that extends from the head portion. The shaft portion is inserted into the insertion hole of the base portion 21. The shaft portion is fixed to the first base body 73. The outer diameter of the shaft portion is smaller than the outer diameter of the head portion. The base portion 21 is pressed by the head portion of the fixing tool to be fixed to the first base body 73.

In the positioning mechanism 2 attached to the second nozzle 72, the base portion 21 is fixed to an outer surface of the second base body 83 by the fixing tools 23 and 24.

The rod holding portion 19 is formed in a rectangular columnar shape. The rod holding portion 19 extends from the tip (tip of the extending portion 22) of the attachment portion 18. The rod holding portion 19 is inclined to descend toward the tip.

As shown in FIG. 8, an insertion hole 25 is formed in the rod holding portion 19. The insertion hole 25 is formed along the longitudinal direction of the rod holding portion 19. The insertion hole 25 is open on a tip surface 19a of the rod holding portion 19. A cross section of the insertion hole 25 orthogonal to the longitudinal direction of the rod holding portion 19 is a circular shape, for example. One or a plurality of insertion holes 19b and 19c that penetrate from an outer surface to an inner surface of the insertion hole 25 are formed in a side portion of the rod holding portion 19.

A portion including the tip of the rod 17 protrudes from the tip of the holder 16. An extending direction of the rod 17 is the same as the longitudinal direction of the rod holding portion 19. The rod 17 is inclined to descend toward the tip.

The rod 17 includes a main body portion 31, a reduced diameter portion 32, and a tip protruding portion 33. For example, the main body portion 31 is formed in a columnar shape. The outer diameter of the main body portion 31 is the same as the inner diameter of the insertion hole 25, or is smaller than the inner diameter of the insertion hole 25. Therefore, the main body portion 31 can be inserted into the insertion hole 25. A scale 34 is formed on an outer peripheral surface of the main body portion 31. The scale 34 indicates a protruding length of the rod 17 from the rod holding portion 19.

The reduced diameter portion 32 protrudes while being reduced in diameter from the tip of the main body portion 31. For example, the reduced diameter portion 32 is formed in a conical shape.

The tip protruding portion 33 protrudes from the tip of the reduced diameter portion 32 in the longitudinal direction of the rod 17. For example, the tip protruding portion 33 is formed in a columnar shape. The outer diameter of the tip protruding portion 33 is smaller than the outer diameter of the main body portion 31.

A tip 33a of the tip protruding portion 33 is the tip of the rod 17. For example, the tip 33a of the tip protruding portion 33 is formed in a hemispherical shape. The tip 33a can engage with the engagement recess 13 of the position confirmation plate 1. For example, the tip 33a is engaged in a state where at least a portion enters the engagement recess 13.

The rod 17 is movable in the longitudinal direction of the rod holding portion 19. The rod 17 is expandable and contractible with respect to the holder 16. The rod 17 can adjust a protruding length from the tip of the rod holding portion 19. The rod 17 is held by the holder 16 (rod holding portion 19) to be expandable and contractible in a direction closer to and away from the position confirmation plate 1.

The rod 17 is fixed to the holder 16 by fixing tools 26 and 27. The fixing tool 26 includes a head portion 26a and a shaft portion 26b (for example, a screw shaft) that extends from the head portion 26a. The fixing tool 27 includes a head portion 27a and a shaft portion 27b (for example, a screw shaft) that extends from the head portion 27a. The shaft portions 26b and 27b are inserted into the insertion holes 19b and 19c of the rod holding portion 19. The tips of the shaft portions 26b and 27b abut against an outer surface of the main body portion 31. For example, the rod 17 is fixed to the holder 16 in a state of being pinched between the fixing tools 26 and 27.

### Nozzle Position Adjusting Method

### First Embodiment

The positions of the nozzles 71 and 72 can be adjusted by using the nozzle position adjusting device 10 before the substrate W is cleaned by using the substrate cleaning device 50. Hereinafter, an example of a method for adjusting the positions of the nozzles 71 and 72 will be described.

### First Step: Installing Position Confirmation Plate

As shown in FIG. 9, the position confirmation plate 1 is installed in the substrate support portion 51. For example, in the position confirmation plate 1, four corner portions are each held by the spindles 54.

### Second Step: Attaching Positioning Mechanism

As shown in FIG. 6, when the position of the first nozzle 71 is adjusted, the positioning mechanism 2 is attached to the first nozzle 71. Specifically, as shown in FIG. 7, the base portion 21 of the holder 16 is fixed to the first base body 73 by the fixing tools 23 and 24.

### Third Step: Adjusting Position of Nozzle

As shown in FIG. 6, an orientation of the first nozzle 71 is adjusted such that the tip (tip 33a (refer to FIG. 8) of the tip protruding portion 33) of the rod 17 engages with the predetermined engagement recess 13 (refer to FIG. 5). For example, in order to adjust the position of the first nozzle 71 of the first liquid supply portion 55, the orientation of the first nozzle 71 is adjusted such that the tip of the rod 17 engages with the engagement recess 13 formed in the position display 11 at a position corresponding to a central portion of the substrate W. The first nozzle 71 whose orientation is adjusted is fixed to the support bodies 59 and 60 by the fixing tools 75 and 76.

When the orientation of the first nozzle 71 is adjusted, the rod 17 is expanded and contracted with respect to the holder 16 when necessary. When the position of the tip of the rod 17 deviates from the target engagement recess 13, the first nozzle 71 can be adjusted again. In this manner, the position of the first nozzle 71 can be determined by using the position display 11.

As in the case of the second nozzle 72, the positioning mechanism 2 is attached to the second nozzle 72, and the orientation of the second nozzle 72 is adjusted such that the tip of the rod 17 engages with the predetermined engagement recess 13 (refer to FIG. 5). The second nozzle 72 is fixed to the support bodies 59 and 60 by the fixing tools 85 and 86. In this manner, the position of the second nozzle 72 can be determined by using the position display 11.

When the positions of the nozzles 71 and 72 are adjusted in this step, it is possible to record whether or not the position of the tip of the rod 17 with respect to the position display 11 matches a design value. This record is effective for management in a subsequent step (for example, a cleaning step performed by the substrate cleaning device 50). For example, despite that the position of the tip of the rod 17 matches the design value, when there is a deviation in a position where the liquid comes into contact with the substrate in the cleaning step, it can be presumed that the deviation occurs due to a cause other than the positions of the nozzles 71 and 72. As the cause other than the positions of the nozzles 71 and 72, for example, a support position of the substrate by the substrate support portion, a flow rate of the liquid, and the like are considered.

After the positions of the nozzles 71 and 72 are completely adjusted, the fixing tools 23 and 24 (refer to FIG. 7) are detached, and the positioning mechanism 2 is detached from the nozzles 71 and 72.

### Advantageous Effects of Nozzle Position Adjusting Device and Nozzle Position Adjusting Method of Embodiment

The nozzle position adjusting device 10 includes the position confirmation plate 1 and the positioning mechanism 2 that extends toward the position confirmation plate 1. Since the positioning mechanism 2 can determine the positions of the nozzles 71 and 72 by using the position display 11, the positions of the nozzles can be quantitatively adjusted. In this manner, variations in the adjustment of an operator can be reduced. The variations in each device can be reduced. Therefore, the positions of the nozzles 71 and 72 can be accurately adjusted. Therefore, in the step of cleaning the substrate W, the nozzles 71 and 72 can jet the cleaning liquid to an accurate position of the substrate W. Therefore, degradation of a cleaning effect which is caused by misalignment of the nozzles 71 and 72 can be suppressed.

The positioning mechanism 2 includes the holder 16 and the rod 17 held by the holder 16 to be expandable and contractible. The positioning mechanism 2 can determine the positions of the nozzles 71 and 72, based on the position of the rod 17 with respect to the position display 11. Therefore, work for adjusting the positions of the nozzles 71 and 72 can be facilitated.

The positioning mechanism 2 can determine the positions of the nozzles 71 and 72 by causing the tip of the rod 17 to engage with the engagement recess 13. Therefore, the misalignment of the tip of the rod 17 with respect to the position confirmation plate 1 is suppressed, and the position of the rod 17 with respect to the position display 11 is easily specified. Therefore, the positions of the nozzles 71 and 72 can be accurately determined.

The position display 11 has the first reference line 11A and the second reference line 11B which have a lattice shape (rectangular lattice shape). The engagement recess 13 is formed at the intersection between the first reference line 11A and the second reference line 11B. Therefore, the position of the rod 17 with respect to the position display 11 is easily specified. Therefore, work for adjusting the positions of the nozzles 71 and 72 can be facilitated.

In the nozzle position adjusting method, the positioning mechanism 2 determines the positions of the nozzles 71 and 72. Therefore, the positions of the nozzles 71 and 72 can be accurately adjusted. Therefore, in the step of cleaning the substrate W, the nozzles 71 and 72 can jet the cleaning liquid to an accurate position of the substrate W. Therefore, degradation of a cleaning effect which is caused by misalignment of the nozzles 71 and 72 can be suppressed.

The holder 16 of the nozzle position adjusting device 10 can determine the positions of the nozzles 71 and 72 by using the rod 17 and the position display 11. Therefore, the positions of the nozzles 71 and 72 can be accurately adjusted. Therefore, in the step of cleaning the substrate W, the nozzles 71 and 72 can jet the cleaning liquid to an accurate position of the substrate W. Therefore, degradation of a cleaning effect which is caused by misalignment of the nozzles 71 and 72 can be suppressed.

### Nozzle Position Adjusting Device

### Second Embodiment

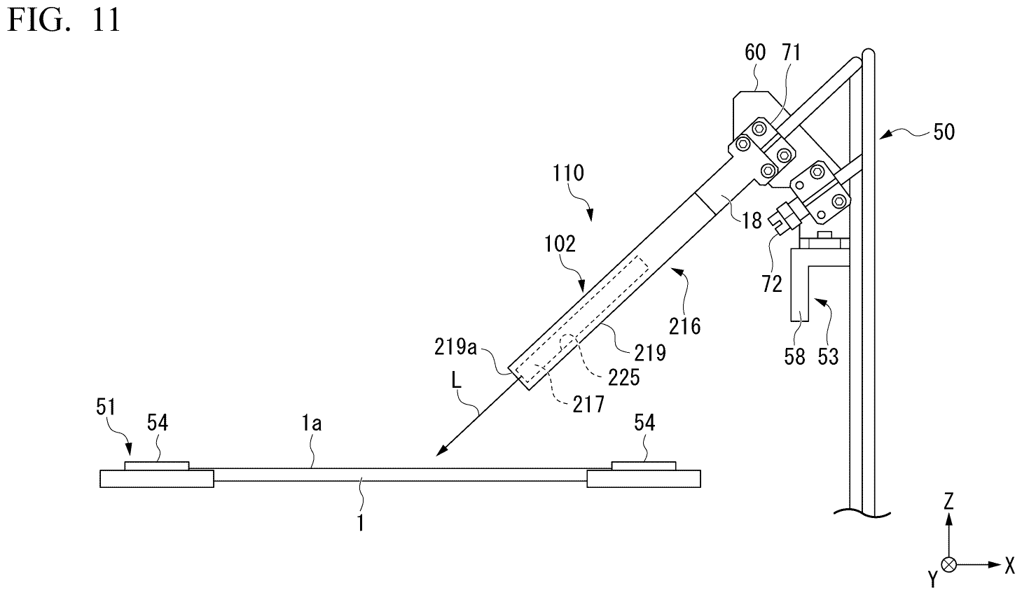

FIG. 11 is a front view of a nozzle position adjusting device 110 according to a second embodiment. The same reference numerals will be assigned to common configurations in the nozzle position adjusting device 10 (refer to FIG. 6) according to the first embodiment, and description thereof will be omitted.

As shown in FIG. 11, the nozzle position adjusting device 110 includes the position confirmation plate 1 and one or the plurality of positioning mechanisms 102.

The positioning mechanism 102 can be detachably attached to the nozzles 71 and 72. The positioning mechanism 102 extends from the attached nozzle toward the position confirmation plate 1.

The positioning mechanism 102 includes a holder 216 and a laser light source 217 (light source). The holder 216 includes the attachment portion 18 and a light source holding portion 219. The light source holding portion 219 extends from the tip of the attachment portion 18. An insertion hole 225 is formed in the light source holding portion 219. The insertion hole 225 is open on a tip surface 219a of the light source holding portion 219. The laser light source 217 can irradiate the first main surface 1a of the position confirmation plate 1 with laser light L through an opening of the insertion hole 225.

### Nozzle Position Adjusting Method

### Second Embodiment

An example of a method for adjusting the positions of the nozzles 71 and 72 by using the nozzle position adjusting device 110 will be described.

The position confirmation plate 1 is installed in the substrate support portion 51. The positioning mechanism 102 is attached to the first nozzle 71. The first main surface 1a of the position confirmation plate 1 is irradiated with the laser light L from the laser light source 217. The orientation of the first nozzle 71 is adjusted such that a predetermined position in the position display 11 is irradiated with the laser light L.

As in the case of the second nozzle 72, the positioning mechanism 102 is attached to the second nozzle 72, and the position confirmation plate 1 is irradiated with the laser light L. The orientation of the second nozzle 72 is adjusted such that a predetermined position in the position display 11 is irradiated with the laser light L. In this way, the positions of the nozzles 71 and 72 can be determined by using the position display 11 of the position confirmation plate 1.

### Advantageous Effects of Nozzle Position Adjusting Device and Nozzle Position Adjusting Method of Embodiment

The nozzle position adjusting device 110 includes the position confirmation plate 1 and the positioning mechanism 102 that extends toward the position confirmation plate 1. The positioning mechanism 102 can determine the positions of the nozzles 71 and 72 by using the position display 11. Therefore, the positions of the nozzles 71 and 72 can be accurately adjusted. Therefore, in the step of cleaning the substrate W, the nozzles 71 and 72 can jet the cleaning liquid to an accurate position of the substrate W. Therefore, degradation of a cleaning effect which is caused by misalignment of the nozzles 71 and 72 can be suppressed.

The positioning mechanism 102 includes the laser light source 217. Therefore, the nozzles 71 and 72 can be positioned by using the laser light L. Therefore, work for adjusting the positions of the nozzles 71 and 72 can be facilitated.

In the nozzle position adjusting method, the positioning mechanism 102 determines the positions of the nozzles 71 and 72 by using the position display 11. Therefore, the positions of the nozzles 71 and 72 can be accurately adjusted. Therefore, in the step of cleaning the substrate W, the nozzles 71 and 72 can jet the cleaning liquid to an accurate position of the substrate W.

The technical scope of the present invention is not limited to the above-described embodiments, and various modifications can be added within the scope not departing from the concept of the present invention.

Although the position confirmation plate 1 shown in FIG. 9 has a rectangular shape, the shape of the position confirmation plate is not particularly limited. For example, the shape of the position confirmation plate may be a circular shape.

Although the plurality of engagement recesses 13 are formed in the position confirmation plate 1, the number of the engagement recesses is not particularly limited. The number of the engagement recesses may be one or more (any number of two or more). Although the engagement recess 13 is formed in the position confirmation plate 1, the engagement recess does not need to be formed in the position confirmation plate. Although the position display 11 has the lattice-shaped reference lines 11A and 11B, the form thereof is not particularly limited as long as the position of the tip of the rod 17 can be specified. For example, the position display may be formed by using a plurality of dots aligned in the X-direction and the Y-direction.

In the positioning mechanism 102 shown in FIG. 11, the laser light source 217 is used, but the light source is not particularly limited. As the light source, for example, a light emitting element such as a light emitting diode (LED) may be used.

In addition, within the scope not departing from the concept of the present invention, configuration elements in the above-described embodiments can be appropriately replaced with well-known configuration elements, and the above-described embodiments or modification examples may be appropriately combined.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

What is claimed is:

1. A nozzle position adjusting device used for a substrate cleaning device including a substrate support portion that supports a substrate and a nozzle that jets a cleaning liquid toward the substrate, the nozzle position adjusting device comprising:
a position confirmation plate in which a position display is formed and which is installed in the substrate support portion; and
a positioning mechanism configured to extend from the nozzle toward the position confirmation plate,
wherein the positioning mechanism determines a position of the nozzle with respect to the position confirmation plate by using the position display.

2. The nozzle position adjusting device according to claim 1,
wherein the positioning mechanism includes a holder and a rod held by the holder to be expandable and contractible in a direction closer to and away from the position confirmation plate, and
the position of the nozzle is determined, based on a position of a tip of the rod with respect to the position display.

3. The nozzle position adjusting device according to claim 2,
wherein one or a plurality of engagement recesses are formed in the position confirmation plate,
the tip of the rod is engageable with the engagement recess, and
the positioning mechanism determines the position of the rod by the tip being engaged with the engagement recess.

4. The nozzle position adjusting device according to claim 3,
wherein the position display has a lattice-shaped reference line, and
the engagement recess is formed at an intersection of the reference line.

5. A nozzle position adjusting method comprising:
installing a position confirmation plate having a position display in a substrate support portion, before cleaning a substrate with a substrate cleaning device including the substrate support portion that supports the substrate and a nozzle that jets a cleaning liquid toward the substrate; and
causing a positioning mechanism configured to extend from the nozzle toward the position confirmation plate to determine a position of the nozzle with respect to the position confirmation plate by using the position display.

6. A nozzle position adjusting holder used for a substrate cleaning device including a substrate support portion that supports a substrate and a nozzle that jets a cleaning liquid toward the substrate,
wherein the nozzle position adjusting holder is used for a nozzle position adjusting device including a position confirmation plate having a position display and installed in the substrate support portion, and a positioning mechanism having a rod and extending from the nozzle toward the position confirmation plate, and
the nozzle position adjusting holder holds the rod to be expandable and contractible in a direction closer to and away from the position confirmation plate.
